(19) United States
(12) Patent Application Publication
(10) Pub. No.: US 2012/0237777 A1
(43) Pub. Date: Sep. 20, 2012

(54) PROCESS FOR FORMING AN ANTI-FOULING COATING SYSTEM

(75) Inventor: Songwei Lu, Wexford, PA (US)

(73) Assignee: PPG INDUSTRIES OHIO, INC., Cleveland, OH (US)

(21) Appl. No.: 13/455,589

(22) Filed: Apr. 25, 2012

Related U.S. Application Data
(63) Continuation-in-part of application No. 13/364,746, filed on Feb. 2, 2012, now abandoned.
(60) Provisional application No. 61/438,751, filed on Feb. 2, 2011.
(60) Provisional application No. 61/480,475, filed on Apr. 29, 2011.

(51) Int. Cl. B05D 3/00; B05D 7/00; B05D 3/10; B32B 27/06; B05D 3/04; B05D 3/06; C23C 16/02; B05D 7/14; B05D 3/12

(52) U.S. Cl. 428/421; 427/299; 427/327; 427/322; 427/307; 427/290; 427/535; 427/558; 427/248.1

(57) ABSTRACT

Provided is a process for forming a durable anti-fouling coating on a substrate including:
(a) modifying a surface of the substrate using a surface modification means;
(b) applying a first coating composition to at least a portion of the modified substrate surface to form a first coating, the composition containing a first perfluoropolyether modified silane;
(c) curing the first coating at a temperature and a relative humidity sufficient to promote hydrolysis of the perfluoropolyether modified silane component;
(d) optionally, modifying the surface of the cured first coating using the same or different surface modification means as was used in (a);
(e) applying a second coating composition to the cured first coating to form a second coating thereover, the composition containing a second perfluoropolyether modified silane; and
(f) curing the second coating at a temperature and a relative humidity sufficient to promote hydrolysis of the second perfluoropolyether modified silane.

### CROSS REFERENCE TO RELATED APPLICATIONS

This application is a continuation-in-part of U.S. patent application No. 13/364,746, filed Feb. 2, 2012 which claims the benefit of priority from U.S. Provisional Application No. 61/438,751 filed Feb. 2, 2011 and U.S. Provisional Application No. 61/480,475, filed Apr. 29, 2011; all of which documents are hereby incorporated herein by reference in their entireties.

### FIELD OF THE INVENTION

The present invention relates to processes for forming anti-fouling coating systems based on perfluoropolyether modified silanes, and to substrates prepared by such processes.

### BACKGROUND OF THE INVENTION

The surfaces of many common devices and appliances are susceptible to staining with fingerprints, skin oil, perspiration, cosmetics, etc. where touch by skin is likely to occur. For example, optical filters and lenses, eyeglass lenses, mirrors, electronic displays such as television screens and displays for handheld devices, as well as stainless steel appliance surfaces, are easily stained with fingerprints and/or cosmetics when used. Once adhering, such stains are not easily removable.

While perfluoropolyether-containing compounds and organic fluoropolymers are known to exhibit water and oil repellency and lubricity due to their low surface energy, such materials typically do not readily form continuous, adherent coatings on other surfaces. Also known in the art are hybrids of perfluoropolyether-containing compounds with organo silane coupling agents. Such hybrid materials exhibit better adhesion to a variety of substrates. However, coatings based on these materials often do not meet the strict durability requirements for application to surfaces that are subjected to frequent handling and touch by skin.

Such surface durability typically is evaluated comparatively using a device that applies a constant pressure on a uniform surface area that cycles from side to side across the coated surface. Long term hydrophobic and oleophobic properties are evaluated by measuring water contact angle after various intervals to obtain the relationship with rubbing cycles, as is described in detail in the Examples herein below.

In addition to durability, anti-fouling coatings must not adversely affect the appearance (aesthetics) of the surface to which they are applied. For most applications, the anti-fouling coating must be transparent, impart no color, and have sufficient rheological properties to allow a uniform, continuous coating layer over the surface(s) to which it is applied.

### SUMMARY OF THE INVENTION

The present invention is directed to a process for forming a durable anti-fouling coating system on a substrate comprising:

(a) modifying a surface of the substrate using a surface modification means;

(b) applying a first coating composition to at least a portion of the modified substrate surface to form a first coating thereover, the first coating composition comprising as a component a first perfluoropolyether modified silane;

(c) curing the first coating at a temperature and a relative humidity sufficient to promote hydrolysis of the perfluoropolyether modified silane component to form a cured first coating on the substrate;

(d) optionally, modifying the surface of the cured first coating using the same or different surface modification means as was used in (a);

(e) applying a second coating composition to at least a portion of the surface of the cured first coating to form a second coating thereover, the second coating composition comprising as a component a second perfluoropolyether modified silane which is the same or different from that comprising the first coating composition; and

(f) curing the second coating at a temperature and a relative humidity sufficient to promote hydrolysis of the second perfluoropolyether modified silane component to form a durable anti-fouling coating system on the substrate.

Substrates coated using the process also are provided.

### DETAILED DESCRIPTION OF THE INVENTION

It is noted that, as used in this specification and the appended claims, the singular forms “a,” “an,” and “the” include plural referents unless expressly and unequivocally limited to one referent.

For the purposes of this specification, unless otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in the following specification and attached claims are approximations that may vary depending upon the desired properties sought to be obtained by the present invention. At the very least, and not as an attempt to limit the application of the doctrine of equivalents to the scope of the claims, each numerical parameter should at least be construed in light of the number of reported significant digits and by applying ordinary rounding techniques.

All numerical ranges herein include all numerical values and ranges of all numerical values within the recited numerical ranges. Notwithstanding that the numerical ranges and parameters setting forth the broad scope of the invention are approximations, the numerical values set forth in the specific examples are reported as precisely as possible. Any numerical value, however, inherently contain certain errors necessarily resulting from the standard deviation found in their respective testing measurements.

As previously mentioned, the present invention provides a process for forming a durable anti-fouling coating system on a substrate comprising:

(a) modifying a surface of the substrate using a surface modification means;

(b) applying a first coating composition to at least a portion of the modified substrate surface to form a first coating thereover, the first coating composition comprising as a component a first perfluoropolyether modified silane;

(c) curing the first coating at a temperature and a relative humidity sufficient to promote hydrolysis of the perfluoropolyether modified silane component to form a cured first coating on the substrate;

(d) optionally, modifying the surface of the cured first coating using the same or different surface modification means as was used in (a);

(e) applying a second coating composition to at least a portion of the surface of the cured first coating to form a second coating thereover, the second coating composition comprising as a component a second perfluoropolyether modified silane which is the same or different from that comprising the first coating composition; and

(f) curing the second coating at a temperature and a relative humidity sufficient to promote hydrolysis of the second perfluoropolyether modified silane component to form a durable anti-fouling coating system on the substrate.

### Substrates:

Substrates suitable for coating by the process of the present invention can include any substrate that might encounter frequent handling, especially substrates that may come into contact with skin oils. Suitable substrates can include, but are not limited to metallic substrates, glass substrate and/or organic polymeric substrates.

Examples of suitable metallic substrates can include ferrous metals and non-ferrous metals. Suitable ferrous metals can include, but are not limited to iron, steel, and alloys thereof. Non-limiting examples of useful steel materials include cold-rolled steel, galvanized (zinc coated) steel, electrogalvanized steel, stainless steel, pickled steel, GALVANNEAL®, GALVALUME®, and GALVAN® zinc-aluminum alloys coated upon steel, and combinations thereof. Useful non-ferrous metals include, but are not limited to aluminum, zinc, magnesium and alloys thereof. Combinations or composites of ferrous and non-ferrous metals can also be used. In a particular embodiment of the present invention, the substrate comprises stainless steel.

As used herein and in the appended claims, the term “glass” is defined as being an inorganic substance, e.g., an inorganic silicate. Glass substrates can be of any type suitable for the intended purpose; but generally are a clear, low colored, transparent glass such as the well-known silica type of glass, particularly soda-lime-silica glass and alumina silicate glass. The nature and composition of various silica glasses are well known in the art. The glass can be a strengthened glass, e.g., strengthening by thermal or chemical tempering.

Organic polymeric substrates that can be used in the process of the present invention are any of the currently known (or later discovered) plastic materials that are useful, for example, as optical substrates chosen from the art-recognized synthetic organic resins, e.g., organic optical resins, that are used to prepare optically clear castings for optical applications, such as for display screens or as ophthalmic lenses. Non-limiting examples of organic polymeric substrates suitable for use in the process of the present invention are polymers, e.g., homopolymers and copolymers, prepared from the monomers and mixtures of monomers disclosed in U.S. Pat. No. 5,962,617, and from column 15, line 28 to column 16, line 17 of U.S. Pat. No. 5,658,501, which disclosure is incorporated by reference. Such organic substrates can be thermoplastic or thermoset polymeric substrates. Such polymeric substrates can include, for example, thermoplastic polymers having a high glass transition temperature, and highly cross-linked polymers. Also, the organic polymeric substrates can be transparent substrates having a refractive index that ranges from 1.48 to 1.74. Alternatively, the organic polymeric substrate can have a refractive index ranging from 1.54 to 1.56, or greater than 1.60, e.g., from 1.60 to 1.74.

Suitable non-limiting specific examples of organic polymeric substrates can include those comprised of: polyol(allyl carbonate) monomers, e.g., allyl diglycol carbonates such as diethylene glycol bis(allyl carbonate), which monomer is sold under the trademark CR-39 by PPG Industries, Inc, and copolymers thereof; polyurea-polyurethane (polyurea urethane) polymers, which are prepared, for example, by the reaction of a polyurethane prepolymer and a diamine curing agent, a composition for one such polymer being sold under the trademark TRIVEX by PPG Industries, Inc; acrylic functional monomers, such as but not limited to, polyol(meth)acryloyl terminated carbonate monomers; diethylene glycol dimethacrylate monomer; ethoxylated phenol methacrylate monomers; diisopropenyl benzene monomer; ethoxylated trimethylol propane triacrylate monomers; ethylene glycol bismethacrylate monomer; poly(ethylene glycol)bismethacrylate monomers; urethane acrylate monomers; poly(ethoxylated bisphenol A dimethacrylate) monomers; poly(vinyl acetate); poly(vinyl alcohol); poly(vinyl chloride); poly(vinylidene chloride); polyolefins, such as polyethylene and polypropylene; polyurethanes; polythiourethanes monomers, which include, but are not limited to materials such as the MR-6, MR-7, MR-8 and MR-10 optical resins sold by Mitsui Chemicals, Inc; thermoplastic polycarbonates, such as the thermoplastic bisphenol A-based polycarbonates, e.g., a carbonate-linked resin derived from bisphenol A and phosgene, one such material being sold under the trademark LEXAN; polyesters, such as the material sold under the trademark MYLAR;. poly(ethylene terephthalate); polyvinyl butyral; poly(methyl methacrylate), such as the material sold under the trademark PLEXIGLAS, and polymers prepared by reacting polyfunctional isocyanate(s) with polythiol(s) or polyepisulfide monomers (such as the monomer sold under the trade name IU-10 by Mitsubishi Gas Chemicals, Inc.), either homopolymerized or co-and/or terpolymerized with polythiols, polyisocyanates, polyisothiocyanates and optionally ethylenically unsaturated monomers or halogenated aromatic-containing vinyl monomers.

### Surface Modifiers:

In the process of the present invention, the surface of the substrate is modified using a “surface modification means” (i.e., a surface modifier). Effective surface modifiers can include treatments such as activated gas treatment, e.g., treatment with a low temperature plasma or corona discharge. Inert gases, such as argon, and reactive gases, such as oxygen, have been used as the plasma gas. Inert gases will roughen the surface, while reactive gases such as oxygen will both roughen and chemically alter slightly the surface exposed to the plasma, e.g., by producing hydroxyl or carboxyl units on the surface. Obviously, the extent of the surface roughening and/or chemical modification will be a function of the plasma gas and the operating conditions of the plasma unit (including the length of time of the treatment).

Additional surface modifiers can include, but are not limited to, UV treatment, and chemical treatment such as with an aqueous solution of acid such as nitric acid or hydrochloric or with a treatment that results in hydroxylation of the substrate surface, e.g., etching of the surface with a caustic solution such as an aqueous solution of alkali metal hydroxide, e.g., sodium or potassium hydroxide, or exposing the surface to a chemical vapor. With respect to glass substrates, suitable surface modification means also can include chemical/mechanical polishing using a polishing pad, such as AQUAPEL® Glass Precleaner towelette or application of any other chemical/mechanical polish, containing materials such as cerium and/or alumina nanoparticles, with or without a subsequent chemical treatment using fluoride-containing glass-etchants. The use of such etchants results in free silicon-oxygen bonds on the glass surface. Such fluoride-containing glass etchants can include, e.g., hydrogen fluoride, hydrofluoric acid, ammonium fluoride, sodium fluoride, sodium bifluoride, potassium fluoride, potassium bifluoride, and/or ammonium hydrogen difluoride (ammonium bifluoride). For stainless steel substrates, ferric chloride can be a suitable etchant. The surface modification means also can include ultrasonication at elevated temperatures above room temperature, rubbing and/or wiping, for example with a cloth or brush.

After modifying the surface of the substrate, a first coating composition is applied to at least a portion of the modified substrate surface to form a first coating thereover. The first coating composition comprises as a component a first perfluoropolyether modified silane.

### Perfluoropolyether Modified Silanes

Many perfluoropolyether modified silane materials are known and widely used. A wide variety of these materials are suitable for use in the first and second coating compositions used in the processes of the present invention. In a particular embodiment of the present invention, the perfluoropolyether modified silane is selected from those having the following Formulas I and/or II.

F—(CF₂)_{q}—(OC₃F₆)ₘ—(OC₂F₄)ₙ—(OC₂F₄)ₙ—(OCF₂)ₒ(CH₂)ₚX(CH)ᵣSi(X′)₃₋ₐ(R¹)ₐ Formula I

F—(CF₂)_{q}—(OC₃F₆)ₘ—(OC₂F₄)ₙ—(OCF₂)ₒ(CH₂)ₚX(C H₂)ᵣ(X′)₂₋ₐ(R¹)ₐSiO(F—(CF₂)_{q}—(OC₃F₆)ₘ—(OC₂F₄)ₙ—(OCF₂)ₒ(CH₂)ₚX(CH₂)ᵣ(X′)₁₋ₐ(R¹)ₐSiO)_{z}F—(CF₂)_{q}—(OC₃F₆)ₘ—(OC₂F₄)ₙ—(OCF₂)ₒ(CH₂)ₚX(CH₂)ᵣ(X′)₂₋ₐ(R¹)ₐSi Formula II

In Formula I, q is an integer from 1 to 3; m, n, and o are independently integers from 0 to 200; p is 1 or 2; X is O or a bivalent organic group; r is an integer from 2 to 20; R¹ is C₁₋₂₂ linear or branched hydrocarbon group; a is an integer from 0 to 2; and X′ is a hydrolysable group. X′ can be, for example, a hydrolysable group chosen from alkoxy groups, such as methoxy, ethoxy, propoxy and butoxy groups; alkoxyalkoxy groups, such as methoxymethoxy and methoxyethoxy; acyloxy such as acetoxy; alkenyloxy groups such as isopropenoxy; and halogen groups such as chloro, bromo and iodo.

In Formula II, q is an integer from 1 to 3; m, n, and o are independently integers from 0 to 200; p is 1 or 2, X is O or a bivalent organic group; r is an integer from 2 to 20; R¹ is a C₁₋₂₂ linear or branched hydrocarbon group; a is an integer from 0 to 2; X′ is a hydrolysable group; and z is an integer from 0 to 10 when a is 0 or 1.

X′ can be, for example, a hydrolysable group chosen from alkoxy groups, such as methoxy, ethoxy, propoxy and butoxy groups; alkooxyalkoxy groups, such as methoxymethoxy and methoxyethoxy; acyloxy such as acetoxy; alkenyloxy groups such as isopropenoxy; and halogen groups such as chloro, bromo and iodo.

Suitable perfluoropolyether modified silanes of the Formulas I and II and the preparation thereof are described in detail in U.S. Published Patent Application No. 2009/0208728 at paragraphs [0030] to [0045], the cited portions of which are incorporated herein by reference.

Alternatively, perfluoropolyether modified silanes suitable for use in the present invention can include those represented by the following Formula III.

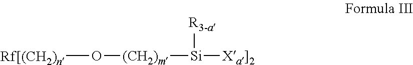

In Formula III, Rf is a divalent straight-chain perfluoro polyether radical; R is C₁ to C₄ alkyl or phenyl; X′ is a hydrolysable group; n′ is an integer from 0 to 2; m′ is an integer from 1 to 5, and a′ is 2 or 3. In a particular embodiment, Rf is the divalent straight-chain perfluoro polyether radical having the formula:

—CF₂CF₂O(CF₂CF₂CF₂O)ₖCF₂CF₂—

or

—CF₂(OC₂F₄)_{p′}(OCF₂)_{q′}—

wherein k, p′ and q′ are each independently an integer of at least 1.

Suitable perfluoropolyether modified silanes of the Formula III and the preparation thereof are described in detail in U.S. Pat. No. 7,196,212 B2 at column 5, line 40 to column 10, line 24, the cited portions of which are incorporated herein by reference.

Alternatively, perfluoropolyether modified silanes suitable for use in the present invention can include those represented by the following Formula IV:

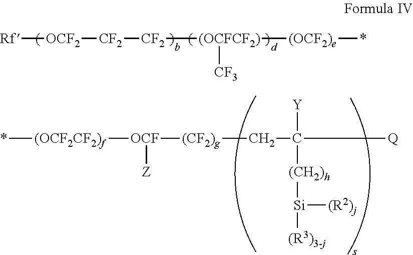

In Formula IV, Rf′ is perfluoroalkyl; Z is fluoro or trifluoroalkyl; b, d, e, f, and g are each independently 0 or an integer of 1 or above, provided that the sum of b+d+e+f+g is not less than 1 and the order of the repeating units parenthesized by subscripts b, d, e, f, and g occurring in the formula is not limited to that shown above; Y is a hydrogen atom or a C₁-C₄ alkyl group; Q is hydrogen, bromo or iodo; R² is hydroxy or a hydrolysable group; R³ is hydrogen or a monovalent hydrocarbon group; h is 0, 1 or 2; j is 1, 2 or 3; and s is an integer of 2 or above.

Suitable perfluoropolyether modified silanes of the Formula IV and the preparation thereof are described in detail in U.S. Pat. No. 6,183,872 B1 at column 5, line 35 to column 15, line 14, the cited portions of which are incorporated herein by reference.

Mixtures of suitable perfluoropolyether modified silanes can be used in the first and second coating compositions used in the processes of the present invention. In a particular embodiment of the present invention, the first perfluoropolyether modified silane is one represented by the Formulas I, II and/or IV.

Typically the perfluoropolyether modified silane is applied in the form of a solution in an appropriate solvent. The solvent can include any of an number of known organic solvents provided that the organic solvent does not react with the perfluoropolyether modified silane (or any other components present in the coating composition). Particularly suitable solvents can include fluorine-containing solvents such as a fluorine-containing alkane, a fluorine-containing haloalkane, a fluorine-containing aromatic, and a fluorine-containing ether, e.g., hydrofluoroether (HFE) such as Novec™ HFE 7100 or 7200 commercially available from 3M Company. Mixtures of appropriate solvents can be used.

The concentration of the perfluoropolyether modified silane present in the first coating composition can range from 0.001 to 80 percent, such as 0.005 to 70 percent, or 0.01 to 60 percent, or 0.01 to 50 percent based on total weight of the first coating composition. The concentration of the perfluoropolyether modified silane present in the first coating composition can range between any of these values inclusive of those recited.

The first coating composition can be applied to the surface modified substrate by any coating method known in the art. Suitable application methods can include, but are not limited to, wet coating methods and dry coating methods. Wet coating methods can include, for example, spray coating, spin coating, dip coating, flow coating, roll coating and like methods. Dry coating methods can include, for example, Physical Vapor Deposition, such as vacuum evaporation, reactive deposition, ion beam assisted deposition, sputtering, ion plating, and like methods; and Chemical Vapor Deposition.

After application of the first coating composition as described above, the first coating is cured at a temperature and a relative humidity sufficient to promote hydrolysis of the perfluoropolyether modified silane component. Obviously, the cure time will be dependent upon the curing temperature and the relative humidity. For example, the first coating can be cured at a temperature of 25° C. and a relative humidity of 40% for a period of 24 hours; or the first coating can be cured at a temperature of 60° C. and a relative humidity of 80% for a period of 2 hours; or the first coating can be cured at a temperature of 130° C. and a measurable relative humidity of greater than 1% for a period of from 0.5 to 1 hour. In a particular embodiment of the present invention, the cure temperature can range from 20° C. to 500° C., such as from 25° C. to 350° C., or from 30° C. to 250° C.; and the relative humidity can range from 1% to 99%, such as from 2% to 95%, or from 5% to 85%. The aforementioned temperature can range between any of the recited temperature values inclusive of the recited temperature values. Likewise, the aforementioned percent relative humidity can range between any of the recited relative humidity values, inclusive of the recited relative humidity values.

If desired, cure times may be reduced through the use of a hydrolytic condensation catalyst. Non-limiting examples of suitable such catalysts can include organic tin compounds (e.g., dibutyltin dimethoxide and dibutyltin dilaurate), organic titanium compounds (e.g., tetra-n-butyl titanate), organic acids (e.g., acetic acid and methanesulfonic acid), and mineral acids (e.g., hydrochloric acid, nitric acid, and sulfuric acid). When employed, the catalyst can be present in a catalytic amount in the first and/or second coating compositions used in the processes of the present invention. For example, the catalyst can be present in the first and/or second coating compositions in an amount ranging from 0.01 to 5 parts by weight, such as from 0.1 to 1 part by weight based on 100 parts of the perfluoropolyether modified silanes present in the first and/or second coating compositions. Alternatively, the catalyst may be present as a vapor during the curing, e.g., as a vapor of a solution of any of the aforementioned organic acids and/or the mineral acids.

In accordance with the process of. the present invention, once the first coating composition is cured to form a cured coating on the surface of the substrate, the surface of the first coating, optionally, is modified using the same or different surface modification means as was used to surface modify the substrate. Any of the aforementioned surface modification means previously described above with respect to the substrate can be used provided the surface modification means does not remove or otherwise compromise the integrity of the first coating. In a particular embodiment of the present invention, the surface modification means used to treat the surface of the first coating results in hydroxylation of the first coating surface. After surface modification of the first cured coating (when a surface modification is used), or after cure of the first coating when surface modification of the first coating is not used, a second coating composition is applied to at least a portion of the modified surface of the cured first coating to form a second coating thereover. The second coating composition can be the same as or different from the first coating composition. The second coating composition comprises as a component a second perfluoropolyether modified silane, which can be the same or different from that comprising the first coating composition. The second coating composition may be any of those compositions described above with respect to the first coating composition. The second coating composition may be identical to the first coating composition; or it may be different. Likewise, the second perfluoropolyether modified silane used in the second coating composition can be the same as the first perfluoropolyether modified silane, or it may be different. In a particular embodiment of the present invention, the second perfluoropolyether modified silane is one represented by the structural formula I, II and/or IV.

Any of the coating application techniques described above with respect to the first coating composition can be used to apply the second coating composition.

After application of the second coating composition to form a second coating over at least a portion of the first coating, the second coating is cured at a temperature and a relative humidity sufficient to promote hydrolysis of the second alkoxysilyl perfluoropolyether adduct component. Curing times, temperatures, and relative humidity for the second coating are as described above with respect to the first coating. The process of the present invention may further comprise wiping, rinsing and/or washing the cured first coating of (c) prior to modifying the surface thereof in (d). Such steps may also be done to the second cured coating of (f).

The process of the present invention provides an adherent, clear, and durable anti-fouling coating system on a variety of substrates. As previously mentioned, surface durability typically is evaluated comparatively using a device that applies a constant pressure on a uniform surface area that cycles from side to side across the coated surface. Long term hydrophobic and oleophobic properties are evaluated by measuring water contact angle after various intervals to obtain the relationship with rubbing cycles, as is described in detail in the examples herein below.

The present invention is more particularly described in the following examples, which are intended to be illustrative only, since numerous modifications and variations therein will be apparent to those skilled in the art.

### EXAMPLES

In Example 1, the surface of the glass substrates was modified and coated twice. The surface of the stainless steel substrates was modified and coated and modified again and coated again. The average value of the Deionized Water (DI) Contact Angle was determined for the treated substrates and uncoated Controls as reported in Table 1. In Example 2, three surface modifying agents and alcohol wiping as Comparative Example 2 were used individually and the substrates were coated twice using the coating used in Example 1. Comparative Example 1 was included which had a modified surface and only one coating. Results of DI water and n-tetradecane Contact Angle are reported in Tables 2 and 3. In Example 3, the procedure of Example 2 was followed using a different coating and results are reported in Tables 4 and 5.

### Example 1

### Part A—Preparation of Coating Solution 1

Into a suitable container equipped with a mixer was added 199.0 grams (g) of HFE-7100 3M™ Novec™ Engineered Fluid from 3M Company and 1.0 g of Dow Corning® 2634 solution (now Dow Corning® 2700 solution) and mixed for 10 minutes.

### Part B—Preparation of Substrates

Ten glass substrates measuring 5.5 mm by 11.0 mm and ten stainless steel substrates measuring 6.0 mm by 10 mm were each immersed in a 12.5 weight percent sodium hydroxide aqueous solution in an ultrasonic bath maintained at 50° C. for 5 minutes; sequentially rinsed in two ultrasonic baths containing deionized (DI) water maintained at 50° C. for 5 minutes in each bath; rinsed with DI water and then with isopropyl alcohol; and dried for 10 minutes in a convection oven maintained at 60° C.

### Part C—Coating of Substrates

### Step 1

Coating Solution 1 (1.0 g) was dispensed over a period of 6 seconds onto each of the glass and stainless steel substrates while spinning for 11 seconds at a speed of 1100 revolutions per minute on a Stir-Pak® spin coater (Cole-Parmer Instrument Company). The coated substrates were placed in a convection oven (20″×20″ size, (50.8×50.8 cm) VWR International, LLC), with the temperature set at 130° C. for 30 minutes. Also in the oven were two wide mouth beakers (150 mm diameter and 75 mm in height) with ¾ of the volume of each filled with DI water. After 30 min, the substrates were removed from the oven and left to cool to room temperature. The surface of each coated substrate was wiped with a soft cloth (AlphaWipe® synthetic wipers).

### Step 2

The coated stainless steel substrates were subjected to the process of Part B again.

### Step 3

The coated stainless steel substrates from Step 2 and the coated glass substrates from Step 1 were coated again following the procedure of Step 1.

### Part D—DI Water Contact Angle Testing

The DI water contact angle was determined using a VCA 2500XE Video Contact Angle system (AST Products, Billerica, Mass.) according to the Operating Manual, VCA 2500 Video Contact Angle System User's Manual, Mar. 17, 1997. DI water (1.0 μl) was dispersed onto the coated substrates of Part C at three different locations. The left contact angle and right contact angle were read from each drop of DI water simultaneously. The average DI water contact angle of the 6 measured values was then calculated and reported in Table 1.

TABLE 1
DI Water Contact Angle for Coated Stainless Steel and Glass Substrates

| Stainless Steel | Left contact | Right contact | Average contact | Glass | Left contact | Right contact | Average contact |
|---|---|---|---|---|---|---|---|
| Substrate | angle (°) | angle (°) | angle (°) | Substrate | angle (°) | angle (°) | angle (°) |
| 1 | 118.2 | 118.3 | 117.1 | 1 | 115.9 | 116.0 | 115.5 |
| | 116.8 | 116.7 | | | 114.4 | 114.6 | |
| | 116.6 | 116.1 | | | 115.9 | 116.1 | |
| 2 | 116.0 | 115.7 | 116.1 | 2 | 116.4 | 116.2 | 116.0 |
| | 116.2 | 116.5 | | | 115.5 | 115.8 | |
| | 116.2 | 116.0 | | | 115.9 | 115.9 | |
| 3 | 115.6 | 115.6 | 115.4 | 3 | 116.7 | 116.7 | 116.4 |
| | 115.2 | 115.4 | | | 115.9 | 115.9 | |
| | 114.8 | 115.5 | | | 116.5 | 116.5 | |
| 4 | 114.2 | 114.3 | 114.6 | 4 | 115.8 | 115.7 | 115.7 |
| | 115.7 | 115.0 | | | 115.4 | 115.6 | |
| | 114.5 | 114.1 | | | 115.8 | 115.8 | |
| 5 | 115.7 | 115.9 | 115.7 | 5 | 115.5 | 115.5 | 115.3 |
| | 116.2 | 116.1 | | | 114.9 | 115.4 | |
| | 115.1 | 115.4 | | | 115.2 | 115.1 | |
| 6 | 110.5 | 110.2 | 112.0 | 6 | 116.4 | 116.5 | 115.8 |
| | 112.3 | 112.3 | | | 115.8 | 115.7 | |
| | 113.3 | 113.3 | | | 115.2 | 115.4 | |
| 7 | 114.3 | 114.3 | 114.1 | 7 | 116.5 | 116.6 | 116.0 |
| | 114.0 | 114.3 | | | 115.9 | 115.8 | |
| | 113.9 | 113.9 | | | 115.5 | 115.4 | |
| 8 | 116.1 | 116.2 | 115.5 | 8 | 116.0 | 116.0 | 115.6 |
| | 115.0 | 115.0 | | | 115.3 | 115.3 | |
| | 115.1 | 115.4 | | | 115.4 | 115.6 | |
| 9 | 114.4 | 114.0 | 114.8 | 9 | 115.0 | 115.1 | 115.1 |
| | 115.4 | 114.0 | | | 115.2 | 115.3 | |
| | 115.6 | 115.4 | | | 115.0 | 115.1 | |
| 10 | 110.9 | 110.9 | 112.0 | 10 | 115.8 | 115.7 | 1 [symbol] 5.8 |
| | 112.4 | 112.7 | | | 115.9 | 116.4 | |
| | 112.3 | 112.8 | | | 115.5 | 115.5 | |
| Control | 92.2 | 918 | 91.6 | Control | 42.4 | 44.3 | 44.6 |
| (Uncoated | 96.2 | 97.2 | | (Uncoated | 49.8 | 52.4 | |
| Stainless | 85.0 | 87.3 | | glass) | 36.4 | 42.2 | |
| steel) | | | | | | | |

### Part E—Permanent Marker Testing

A stainless steel substrate and a glass substrate were each coated with Coating Solution 1 following the steps of Parts B and C, except that EUROLENS® Model 1400 lens saver tape was applied to about half of the surface of each substrate prior to Part C. The resulting substrates were marked with a Sharpie® King size™ permanent marker across both the coated and uncoated surfaces. A marker line of about 5 mm width was observed on the uncoated surfaces but on the coated side only beads of the marker ink were present. The beads were easily removed with the previously described soft cloth but the marker on the uncoated surface was not removable.

### Example 2

### Part A—Preparation of Coating Solution A1

Into a suitable container equipped with a mixer was added 199.0 grams (g) of HFE-7100 3M™ Novec™ Engineered Fluid from 3M Company and 1.0 g of Dow Corning® 2634 solution (now Dow Corning® 2700 solution) and mixed for 10 minutes.

### Part B—Preparation of Substrates

Microscope slide glass substrates from Thermo Fisher Scientific Inc. measuring 7.6 mm—5.1 mm×1.2 mm were used as substrates in Part B. Substrates designated as PA1 and Comparative Example 1 (CE-1) were each immersed in a 2.0 weight percent ammonium fluoride aqueous solution at room temperature for 1 minute; sequentially rinsed in two baths containing deionized (DI) water maintained at room temperature for 1 minute in each bath; then rinsed with isopropyl alcohol; and dried for 10 minutes in a convection oven maintained at 60° C.

Substrate QA1 was immersed in a 12.5 weight percent sodium hydroxide aqueous solution in an ultrasonic bath maintained at 50° C. for 5 minutes; sequentially rinsed in two ultrasonic baths containing deionized (DI) water maintained at 50° C. for 5 minutes in each bath; rinsed with DI water and then with isopropyl alcohol; and dried for 10 minutes in a convection oven maintained at 60° C.

Substrate RA1 was immersed in a 5.0 weight percent hydrochloric acid aqueous solution at room temperature for 1 minute; sequentially rinsed in two baths containing deionized (DI) water maintained at room temperature for 1 minute in each bath; then rinsed with isopropyl alcohol; and dried for 10 minutes in a convection oven maintained at 60° C.

Substrate Comparative Example 2 (CE-2) was wiped with isopropyl alcohol and then dried at room temperature.

### Part C—Coating of Substrates

### Step 1

Coating Solution A1 (1.0 g) was dispensed over a period of 6 seconds onto each of the substrates (PA1, QA1, RA1, CE-1 and CE-2) while spinning for 11 seconds at a speed of 1100 revolutions per minute on a StirPak® spin coater (Cole-Parmer Instrument Company). The coated substrates were placed in a convection oven with the temperature set at 200° C. for 5 minutes. After 5 minutes, the substrates were removed from the oven and left to cool to room temperature. The surface of each coated substrate was wiped with a soft cloth (AlphaWipe® synthetic wipers) with isopropyl alcohol.

### Step 2

The coated glass substrates from Step 1 were coated again following the procedure of Step 1, except that the CE-1 substrate was not coated again.

### Part D—DI Water Contact Angle Testing

The DI water contact angle was determined following the procedure of Part D of Example 1. The contact angle was also measured using n-tetradecane (Sigma-Aldrich Co. LLC.) and those results are also listed in Tables 2 and 3.

### Part E—Wear Durability Testing

Wear durability of the coated substrates were measured using a 5750 Linear Abraser (Taber Industries, Inc.) with 60 cycles per minute speed, at 2000 cycles interval with a total of 6000 cycles under 1000 g weight, using #0000 steel wool (Colts Laboratories) to abrade the coated surface. After each 2000 cycles, contact angles were measured on duplicate substrates unless noted otherwise using DI water and n-tetradecane as described in Part D. An arithmetic average is reported in the Tables.

In Table 2, sample PA1 coated with two coatings demonstrated better wear durability, i.e. slower contact angle reduction than Comparative Example 1 coated with one coating. Five replicate substrates of Comparative Example 1 were tested.

In Table 3, different levels of wear durability are demonstrated with substrates PA1 with ammonium fluoride aqueous etching; QA1 with aqueous caustic etching, RA1 with hydrochloric acid aqueous solution etching, and CE-2 with isopropyl alcohol wiping. Triplicate substrates were tested for QA1, RA1 & CE-2.

TABLE 2
DI Water and n-Tetradecane Contact Angle for Coated Glass Substrates

| | | Contact angles (°) after the number of wear cycles indicated | | | | | | | |
|---|---|---|---|---|---|---|---|---|---|
| Sample | | DI water | | | | n-Tetradecane | | | |
| ID | Coating | 0 | 2000 | 4000 | 6000 | 0 | 2000 | 4000 | 6000 |
| PA1 | Two coats | 113.6 | 112.6 | 111.4 | 107.4 | 65.3 | 65.0 | 64.5 | 62.6 |
| CE-1 | One coat | 114.0 | 100.2 | 91.4 | 76.0 | 65.6 | 63.0 | 51.4 | 40.8 |

TABLE 3
DI Water and n-Tetradecane Contact Angle for Coated Glass Substrates with two coatings

| | | Contact angles (°) after the number of wear cycles indicated | | | | | | | |
|---|---|---|---|---|---|---|---|---|---|
| Sample | | DI water | | | | n-Tetradecane | | | |
| ID | Etching solution | 0 | 2000 | 4000 | 6000 | 0 | 2000 | 4000 | 6000 |
| PA1 | 2.0 wt % ammonium | 113.5 | 112.6 | 111.4 | 107.4 | 65.3 | 65.0 | 64.5 | 62.6 |
| | fluoride aqueous solution | | | | | | | | |
| QA1 | 12.5 wt % sodium | 114.9 | 94.6 | 83.9 | 79.1 | 65.2 | 56.7 | 49.3 | 42.9 |
| | hydroxide aqueous solution | | | | | | | | |
| RA1 | 5.0 wt % hydrochloric | 115.3 | 108.9 | 101.9 | 102.4 | 65.5 | 65.1 | 62.2 | 58.1 |
| | acid aqueous solution | | | | | | | | |
| CE-2 | Wipe with isopropyl alcohol | 114.6 | 97.1 | 75.4 | 60.3 | 65.2 | 60.9 | 42.6 | 27.8 |

### Example 3

### Part A—Preparation of Coating Solution A2

Into a suitable container equipped with a mixer was added 198.0 grams (g) of HFE-7100 3M™ Novec™ Engineered Fluid from 3M Company and 2.0 g of OPTOOL® DSX from Daikin Industries, Ltd. and mixed for 10 minutes.

### Part B—Preparation of Substrates

Microscope slide glass substrates were prepared following the procedures of Part B of Example 2 producing modified surfaces on slides PA2; QA2; RA2; CE-3 and CE-4.

### Part C—Coating of Substrates

The procedure of Part C of Example 2 was followed using Coating Solution A2 producing substrates having two coatings on substrates PA2, QA2, RA2, and CE-4 and one coating on substrate CE-3.

### Part D—DI Water Contact Angle Testing

The DI water contact angle was determined following the procedure of Part D of Example 1. The contact angle was also measured using n-tetradecane (Sigma-Aldrich Co. LLC.) and those results are also listed in Tables 4 and 5.

### Part E—Wear Durability Testing

Wear durability of the coated substrates was measured following the procedure of Part E of Example 2.

In Table 4, sample PA2 coated with two coatings demonstrated better wear durability, i.e. slower contact angle reduction than Comparative Example 3 coated with one coating.

In Table 5, different levels of wear durability are demonstrated with substrates PA2 with ammonium fluoride aqueous etching; QA2 with aqueous caustic etching, RA2 with hydrochloric acid aqueous solution etching, and Comparative Example 4 with isopropyl alcohol wiping. Three replicates were measured for CE-4.

TABLE 4
DI Water and n-Tetradecane Contact Angle for Coated Glass Substrates

| | | Contact angles (°) after the number of wear cycles indicated | | | | | | | |
|---|---|---|---|---|---|---|---|---|---|
| Sample | | DI water | | | | n-Tetradecane | | | |
| ID | Coating | 0 | 2000 | 4000 | 6000 | 0 | 2000 | 4000 | 6000 |
| PA2 | Two coats | 114.6 | 111.7 | 107.9 | 108.8 | 66.3 | 65.5 | 63.2 | 63.4 |
| CE-3 | One coat | 113.9 | 109.9 | 105.2 | 102.9 | 66.0 | 64.3 | 59.8 | 57.2 |

TABLE 5
DI Water and n-Tetradecane Contact Angle for Coated Glass Substrates with two coatings

| | | Contact angles (°) after the number of wear cycles indicated | | | | | | | |
|---|---|---|---|---|---|---|---|---|---|
| Sample | | DI water | | | | n-Tetradecane | | | |
| ID | Etching solution | 0 | 2000 | 4000 | 6000 | 0 | 2000 | 4000 | 6000 |
| PA2 | 2.0 wt % ammonium | 114.6 | 111.7 | 107.9 | 108.8 | 66.3 | 65.5 | 63.2 | 63.4 |
| | fluoride aqueous solution | | | | | | | | |
| QA2 | 12.5 wt % sodium | 113.9 | 104.9 | 94.3 | 85.9 | 66.1 | 61.3 | 55.5 | 50.7 |
| | hydroxide aqueous solution | | | | | | | | |
| RA2 | 5.0 wt % hydrochloric | 114.5 | 107.6 | 95.3 | 89.7 | 65.8 | 63.2 | 56.4 | 49.2 |
| | acid aqueous solution | | | | | | | | |
| CE-4 | Wipe with isopropyl alcohol | 112.5 | 103.7 | 96.9 | 91.1 | 64.8 | 63.3 | 57.4 | 47.5 |

Whereas the present invention has been described with reference to specific details of particular embodiments thereof, it is not intended that such details be regarded as limitations upon the scope of the invention except insofar as and to the extent that they are included in the appended claims.

I claim:

1. A process for forming a durable anti-fouling coating system on a substrate comprising:
(a) modifying a surface of the substrate using a surface modification means;
(b) applying a first coating composition to at least a portion of the modified substrate surface to form a first coating thereover, the first coating composition comprising as a component a first perfluoropolyether modified silane;
(c) curing the first coating at a temperature and a relative humidity sufficient to promote hydrolysis of the perfluoropolyether modified silane component to form a cured first coating on the substrate;
(d) optionally, modifying the surface of the cured first coating using the same or different surface modification means as was used in (a);
(e) applying a second coating composition to at least a portion of the surface of the cured first coating to form a second coating thereover, the second coating composition comprising as a component a second perfluoropolyether modified silane which is the same or different from that comprising the first coating composition; and
(f) curing the second coating at a temperature and a relative humidity sufficient to promote hydrolysis of the second perfluoropolyether modified silane component to form a durable anti-fouling coating system on the substrate.

2. The process of claim 1, wherein the substrate comprises metallic substrates, glass substrate and/or polymeric substrates.

3. The process of claim 1, wherein the first coating composition and the second coating composition are the same composition.

4. The process of claim 1, wherein the surface modification means is selected from contacting with acidic solution, contacting with a fluoride containing etchant solution, contacting with a ferric chloride etchant solution, contacting with caustic solution, treating with plasma, treating with corona, exposing to UV radiation, chemical/mechanical polishing and/or exposing to a chemical vapor.

5. The process of claim 1, wherein the surface modification means used in (a) and (d) are the same.

6. The process of claim 5, wherein the surface modification means is contacting with caustic solution and/or a ferric chloride etchant solution.

7. The process of claim 5, wherein the substrate is stainless steel.

8. The process of claim 1, wherein the surface modification means in (a) and (d) are different.

9. The process of claim 8, wherein the substrate is glass.

10. The process of claim 9, wherein the surface modification means is contacting with caustic solution and/or a contacting a fluoride containing etchant solution.

11. The process of claim 9, wherein the surface modification means is chemical/mechanical polishing and/or contacting with a fluoride containing etchant solution.

12. The process of claim 1, wherein the perfluoropolyether modified silane is selected from Formula I or II:
F—(CF₂)_{q}—(OC₃F₆)ₘ—(OC₂F₄)ₙ—(OCF₂)ₒ(CH₂)ₚX(CH₂)ᵣSi(X′)₃₋ₐ(R¹)ₐ Formula I
wherein in Formula I, q is an integer from 1 to 3; m, n, and o are independently integers from 0 to 200; p is 1 or 2; X is O or a bivalent organic group; r is an integer from 2 to 20; R¹ is C₁₋₂₂ linear or branched hydrocarbon group; a is an integer from 0 to 2; and X′ is a hydrolysable group; and
F—(CF₂)_{q}—(OC₃F₆)ₘ—(OC₂F₄)ₙ—(OCF₂)ₒ(CH₂)ₚX(CH₂)ᵣ(X′)₂₋ₐSiO(F—(CF₂)_{q}—(OC₃F₆)ₘ—(OC₂F₄)ₙ—(OCF₂)ₒ(CH₂)ₚX(CH₂)ᵣ(X′)₁₋ₐ(R¹)ₐSiO)_{z}F—(CF₂)_{q}—(OC₃F₆)ₘ—(OC₂F₄)ₙ—(OCF₂)ₒ(CH₂)ₚX(CH₂)₁(X′)₂₋ₐ(R¹)ₐSi Formula II
wherein q is an integer from 1 to 3; m, n, and o are independently integers from 0 to 200; p is 1 or 2, X is O or a bivalent organic group; r is an integer from 2 to 20; R¹ is a C₁₋₂₂ linear or branched hydrocarbon group; a is an integer from 0 to 2; X′ is a hydrolysable group;
and z is an integer from 0 to 10 when a is 0 or 1.

13. The process of claim 1, wherein the perfluoropolyether modified silane has the following Formula III: 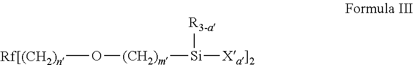
wherein Rf is a divalent straight-chain perfluoropolyether radical; R is C₁₋₄ alkyl or phenyl; X′ is a hydrolysable group; n′ is an integer from 0 to 2; m′ is an integer from 1 to 5, and a′ is 2 or 3.

14. The process of claim 13, wherein Rf is a divalent straight chain perfluoropolyether radical having the formula:
—CF₂CF₂O(CF₂CF₂CF₂O)ₖCF₂CF₂—
or
—CF₂(OC₂F₄)_{p′}(OCF₂)_{p′}
wherein k, p′ and q′ are each independently an integer of at least 1.

15. The process of claim 1, wherein the perfluoropolyether modified silane is selected from Formula IV: 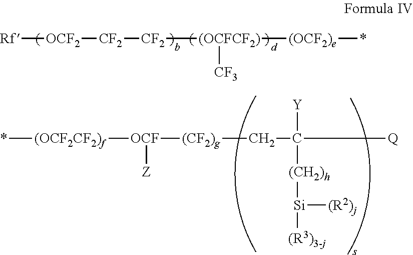
wherein Rf′ is perfluoroalkyl; Z is fluoro or trifluoroalkyl; b, d, e, f, and g are each independently 0 or an integer of 1 or above, provided that the sum of b+d+e+f+g is not less than 1 and the order of the repeating units parenthesized by subscripts b, d, e, f, and g occurring in the formula is not limited to that shown above; Y is a hydrogen atom or a C₁-C₄ alkyl group; Q is hydrogen, bromo or iodo; R₂ is hydroxy or a hydrolysable group; R₃ is hydrogen or a monovalent hydrocarbon group; h is 0, 1 or 2; j is 1, 2 or 3; and s is an integer of 2 or above.

16. The process of claim 1, wherein the cure temperature ranges from 20° C. to 500° C., and the relative humidity ranges from 99% to 1%.

17. The process of claim 16, wherein the cure temperature ranges from 30° C. to 250° C., and the relative humidity ranges from 85% to 5%.

18. The process of claim 1, further comprising wiping, rinsing and/or washing the cured first coating of (c) prior to modifying the surface thereof in (d).

19. The process of claim 16, further comprising wiping, rinsing and/or washing the cured second coating of (f).

20. The process of claim 11, wherein the fluoride containing glass etchant solution comprises a fluoride containing etchant chosen from hydrogen fluoride, hydrofluoric acid, ammonium fluoride, sodium fluoride, sodium bifluoride, potassium fluoride, potassium bifluoride, and/or ammonium bifluoride.

21. A coated substrate prepared by the process of claim 1.
